(19) United States
(12) Patent Application Publication
(10) Pub. No.: US 2017/0017544 A1
(43) Pub. Date: Jan. 19, 2017

(54) SYSTEMS AND METHODS FOR PROVIDING LOW LATENCY READ PATH FOR NON-VOLATILE MEMORY

(71) Applicant: HGST Netherlands B.V., Amsterdam (NL)

(72) Inventors: Zvonimir Z. Bandic, San Jose, CA (US); Kiran Kumar Gunnam, Milpitas, CA (US); Minghai Qin, San Jose, CA (US); Dejan Vucinic, San Jose, CA (US)

(21) Appl. No.: 14/963,025

(22) Filed: Dec. 8, 2015

Related U.S. Application Data
(60) Provisional application No. 62/192,513, filed on Jul. 14, 2015.

(51) Int. Cl. G06F 11/10; H03M 13/15; G11C 29/52

(52) U.S. Cl. CPC G06F 11/1068; G11C 29/52; H03M 13/153; H03M 13/1545; H03M 13/1575

(57) ABSTRACT

Aspects of the disclosure relate to storage systems for providing low latency read access of a non-volatile memory. One such system includes a non-volatile memory (NVM) configured for read access via a primary data path, a syndrome checker disposed along the primary read data path and configured to check a codeword read from the NVM for errors, an error correction code circuitry disposed outside of the primary data path and, if the codeword is determined to contain an error, configured to determine a location of the error in the codeword, and a queue disposed along the primary read data path. The queue is configured to receive the codeword from the syndrome checker and output the codeword to a host. If the codeword is determined to contain the error, the queue corrects the error based on the determined location of the error from the error correction code circuitry.

### CROSS-REFERENCE TO RELATED APPLICATION(S)

This application claims priority to and the benefit of U.S. Provisional Application No. 62/192,513, filed on Jul. 14, 2015, having Attorney Docket No. HGST-1004P (H20151150) and entitled, “SYSTEMS AND METHODS FOR PROVIDING LOW LATENCY READ PATH FOR NON-VOLATILE MEMORY”, the entire content of which is incorporated herein by reference.

### FIELD

Aspects of the disclosure relate generally to storage systems, and more specifically, to systems and methods for providing a low latency read path for non-volatile memories.

### BACKGROUND

Non-volatile memory (NVM) devices such as those used in solid state devices (e.g., flash memory and the like) often need error correcting codes in order to prevent information loss. Bit error rates in such memory devices are increasing with each new device generation as semiconductor feature sizes are reduced, operating speeds are increased, and the number of bits per memory cell is increased.

In a flash memory device such as a NAND gate-based memory device, data is generally stored in blocks of 512 bytes, corresponding to blocks of 4096 bits. Parity bits are added to each block of data so that a number of bit errors can be detected and corrected. For example, in a block of 512 bytes 78 parity bits can be added to the 512 bytes to provide error detection and correction capability for up to six bits. In other examples, a flash memory device may have other configurations.

Hardware solutions with programmable error correction capability using Reed-Solomon codes have been used for various error detection and correction applications, e.g., magnetic memory devices such as hard disk drives which generally produce bursts of errors. However, flash memory devices tend to suffer from isolated random errors. Bose-Chaudhuri-Hocquenghem (BCH) codes are often the chosen protection technique for the random errors encountered in non-volatile memory devices.

In some instances, the BCH codes may be used in high speed data paths (e.g., Gigabytes per second). The problems involved in providing error correction schemes on high speed data paths, such as 4 Gigabytes per second (GBytes/s), are the corresponding consumption of significant circuit area and power for conventional implementations. In one high speed application example, the system targets handling 28.8 GBytes/s while tolerating a raw bit error rate (BER) of 1e-5, which is even more challenging. The considered code can be of length 572 bit with code rate 0.8951. For example, the code may use 512 data bits and 64 parity bits to handle a raw bit error rate of 1e-5 to provide an uncorrectable bit error rate (UBER) of 3.2e-20. UBER is the number of data errors per bit read after applying a certain error-correction method.

Some solutions for high speed data paths specify a raw BER close to zero such that there is no more than one error in the received codeword. These solutions often employ relatively simple techniques such as single error correction (SEC) and double error detection (DED). However, these approaches are inadequate for providing fast error correction and minimal area consumption.

### SUMMARY

In one embodiment, the disclosure relates to a storage system for providing low latency read access of a non-volatile memory, the system including a non-volatile memory (NVM) configured for read access via a primary data path, a syndrome checker disposed along the primary read data path and configured to check a codeword read from the NVM for errors, an error correction code circuitry disposed outside of the primary data path and, if the codeword is determined to contain an error, configured to determine a location of the error in the codeword, and a queue disposed along the primary read data path. The queue is configured to receive the codeword from the syndrome checker. If the codeword is determined to contain no errors, the queue outputs the codeword to a host. If the codeword is determined to contain the error, the queue corrects the error based on the determined location of the error from the error correction code circuitry and outputs the codeword to the host.

In another embodiment, the disclosure relates to a method for providing low latency read access of a non-volatile memory where the method involves reading a codeword from a non-volatile memory (NVM), determining whether the codeword contains an error, sending, if the codeword does not contain the error, the codeword to a queue or host without attempting to locate errors in the codeword, determining, if the codeword contains the error, a location of the error in the codeword, and correcting, if the codeword contains the error, the error in the codeword based on the determined location.

In another embodiment, the disclosure relates to an error correction code (ECC) circuitry, the ECC circuitry including a syndrome queue configured to store one or more syndromes of a codeword, an error location queue configured to store one or more error locations of the codeword, a first data path coupled between the syndrome queue and the error location queue, and a second data path coupled in parallel to the first data path. If the codeword has a number of errors less than or equal to a threshold, components in the first data path are configured to determine the one or more error locations. If the codeword has a number of errors greater than the threshold, components in the second data path are configured to determine the one or more error locations. The components in the first data path are configured to determine the error locations faster than that of the second data path.

### BRIEF DESCRIPTION OF THE DRAWINGS

FIG. 1 is a block diagram of a solid state device with a low latency read path architecture configured for high throughput error correction in accordance with one embodiment of the disclosure.

FIG. 2 is a block diagram of a low latency read path architecture having an error correction code (ECC) circuitry disposed outside of a primary read path in accordance with one embodiment of the disclosure.

FIG. 3 is a block diagram of an error correction code (ECC) circuitry in accordance with one embodiment of the disclosure.

FIG. 4 is a flowchart of a first process for determining and solving an error location polynomial for a codeword in accordance with one embodiment of the disclosure.

FIG. 5 is a flowchart of a second process for determining and solving an error location polynomial for a codeword in accordance with one embodiment of the disclosure.

FIG. 6 is a flowchart of a process for providing low latency read access of a non-volatile memory in accordance with one embodiment of the disclosure.

### DETAILED DESCRIPTION

Referring now to the drawings, embodiments of systems and methods for providing low latency read access of a non-volatile memory are illustrated. One such system includes a non-volatile memory (NVM) configured for read access via a primary data path, a syndrome checker disposed along the primary read data path and configured to check a codeword read from the NVM for errors, and an error correction code (ECC) circuitry disposed outside of the primary data path. If the codeword is determined to contain an error, the ECC circuity is configured to determine a location of the error in the codeword. In addition, a queue is disposed along the primary read data path, and is configured to receive the codeword from the syndrome checker. If the codeword is determined to contain no errors, the queue outputs the codeword to a host, and if the codeword is determined to contain the error, the queue corrects the error based on the determined location of the error from the error correction code circuitry and outputs the codeword to the host.

In several embodiments, the error correction code (ECC) circuitry is effectively decoupled from the primary data path and from processing each read data for error locations, and thereby acting or activated only when the syndrome checker finds an error in the data (e.g., codeword) received. In some embodiments, the systems and methods described herein can also be applied to other sources of data (e.g., wireless channel) that have relatively low noise (e.g., low error counts possibly less than 1e-4).

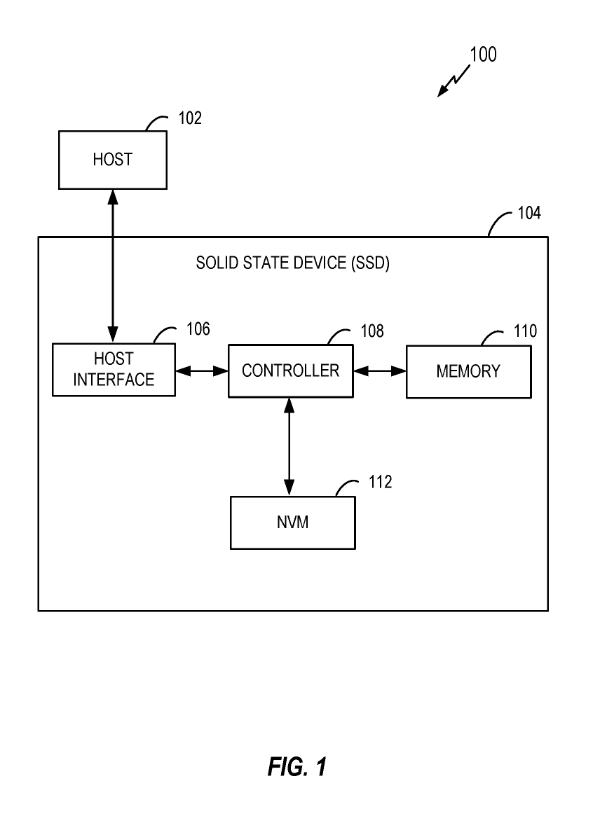

FIG. 1 is a block diagram of a solid state device (SSD) with a low latency read path architecture configured for high throughput error correction in accordance with one embodiment of the disclosure. The system 100 includes a host 102 and a SSD storage device 104 coupled to the host 102. The host 102 provides commands to the SSD storage device 104 for transferring data between the host 102 and the SSD storage device 104. For example, the host 102 may provide a write command to the SSD storage device 104 for writing data to the SSD storage device 104, or a read command to the SSD storage device 104 for reading data from the SSD storage device 104. The host 102 may be any system or device having a need for data storage or retrieval and a compatible interface for communicating with the SSD storage device 104. For example, the host 102 may be a computing device, a personal computer, a portable computer, a workstation, a server, a personal digital assistant, a digital camera, a digital phone, an Internet of Things (IoT) device, or the like.

The SSD storage device 104 includes a host interface 106, a controller 108, a memory 110, and a non-volatile memory 112. The host interface 106 is coupled to the controller 108 and facilitates communication between the host 102 and the controller 108. Additionally, the controller 108 is coupled to the memory 110 and the non-volatile memory 112. The host interface 106 may be any type of communication interface, such as an Integrated Drive Electronics (IDE) interface, a Universal Serial Bus (USB) interface, a Serial Peripheral (SP) interface, an Advanced Technology Attachment (ATA) interface, a Peripheral Component Interconnect Express (PCIe) interface, a Small Computer System Interface (SCSI), an IEEE 1394 (Firewire) interface, or the like. In some embodiments, the host 102 includes the SSD storage device 104 (e.g., integrated storage). In other embodiments, the SSD storage device 104 is remote with respect to the host 102 or is contained in a remote computing system coupled in communication with the host 102. For example, the host 102 may communicate with the SSD storage device 104 through a wireless communication link.

The controller 108 controls the operation of the SSD storage device 104. In various embodiments, the controller 108 receives commands from the host 102 through the host interface 106 and performs the commands to transfer data between the host 102 and the non-volatile memory 112. The controller 108 may include any type of processing device, such as a microprocessor, a microcontroller, an embedded controller, a logic circuit, software, firmware, or the like, for controlling the operation of the SSD storage device 104. Additionally, the controller 108 can be configured to perform additional functions to be described below.

In some embodiments, some or all of the functions described herein as being performed by the controller 108 may instead be performed by another element of the SSD storage device 104. For example, the SSD storage device 104 may include a microprocessor, a microcontroller, an embedded controller, a logic circuit, software, firmware, or any kind of processing device, for performing one or more of the functions described herein as being performed by the controller 108. In some embodiments, one or more of the functions described herein as being performed by the controller 108 are instead performed by the host 102. In some embodiments, some or all of the functions described herein as being performed by the controller 108 may instead be performed by another element such as a controller in a hybrid drive including both non-volatile memory elements and magnetic storage elements.

The memory 110 may be any memory, computing device, or system capable of storing data. For example, the memory 110 may be a random-access memory (RAM), a dynamic random-access memory (DRAM), a static random-access memory (SRAM), a synchronous dynamic random-access memory (SDRAM), a flash storage, an erasable programmable read-only-memory (EPROM), an electrically erasable programmable read-only-memory (EEPROM), or the like. In various embodiments, the controller 108 uses the memory 110, or a portion thereof, to store data during the transfer of data between the host 102 and the non-volatile memory 112. For example, the memory 110 or a portion of the memory 110 may be a cache memory. The controller 108 when executing programs or instructions, may use the memory 110 for temporary data storage.

The non-volatile memory 112 receives data from the controller 108 and stores the data. The non-volatile memory 112 may be any type of non-volatile memory, such as a flash storage system, a solid state drive, a flash memory card, a secure digital (SD) card, a universal serial bus (USB) memory device, a CompactFlash card, a SmartMedia device, a flash storage array, or the like.

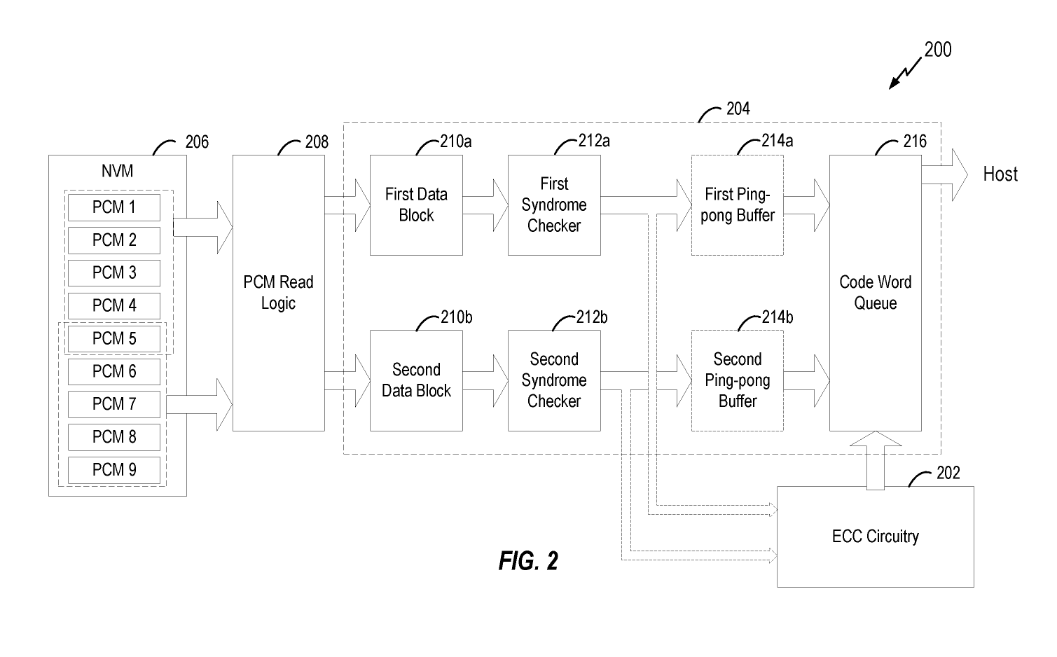

FIG. 2 is a block diagram of a low latency read path architecture/system 200 having an error correction code (ECC) circuitry 202 disposed outside of a primary read path 204 in accordance with one embodiment of the disclosure. In one embodiment, the system 200 can be implemented in the controller 108 and/or NVM 112 of FIG. 1. In another embodiment, the system 200 can be formed as a separate component attached to both the controller 108 and the NVM 112 and implemented using an ASIC, an FPGA, or other suitable hardware (e.g., such as the hardware described above for the controller 108).

The system 200 further includes a non-volatile memory 206, a PCM read logic 208, first and second data blocks (210a, 210b), first and second syndrome checkers (212a, 212b), first and second ping-pong buffers 214a, 214b, and a code word queue 216. In one embodiment, the non-volatile memory 206 may include a number of phase change memory (PCH) chips (e.g., PCH chip 1-9), and the PCM read logic 208 may include circuitry configured to read data from the non-volatile memory 206. The read data (codewords) may be encoded using BCH error correction codes. BCH codes can be designed to provide control over the number of bit errors correctable by the code. In one embodiment, a PCM chip includes a number of memory cells, and the PCM read logic 208 is configured to read the cells by selecting the corresponding rows and columns. In one example, after the cell is selected, the PCM read logic 208 activates the selected cell, senses the change in a voltage level of the cell, and reads the data stored in the selected cell.

In one embodiment, the first data block 210a receives 16 user data bytes from PCM chips 1 to 4 and 2 parity bytes from PCM chip 5 operating at about 800 mega-hertz (MHz). The second data block 210b receives 16 user data bytes from PCM chips 6 to 9 and 2 parity bytes from PCM chip 5 operating at about 800 MHz. The first data block 210a and second data block 210b each include storage locations (e.g., registers or buffers) for storing the user data bytes and parity bytes read from the corresponding PCM chips. The data blocks (210a and 210b) may temporarily store the data read from the NVM 206 and provide the stored data to the corresponding syndrome checker (212a and 212b). The first data block 210a and/or second data block 20b may be configured to present the data at the rate at which the syndrome checkers 214a and 214b can process or handle. In other embodiments, other suitable data block configurations and speeds can be used. For example, the first data block 210a and second data block 210b may be included in the same device. In some examples, the first data block 210a may be included in the first syndrome checker 212a, and the second data block 210b may be included in the second syndrome checker 212b.

The first syndrome checker 212a is configured to determine one or more syndromes corresponding to the codeword (encoded bits or data) received from the first data block 210a. The codeword may be represented as a polynomial. The syndrome checkers may be implemented in any suitably known techniques. The syndromes are checked to determine whether or not the codeword contains error bit(s). For example, a non-zero syndrome indicates the codeword has error. The received data or codeword from the NVM can be represented as follows:

r=c+e Equation (1)

In equation (1), r is the received data; c is the codeword; and e is the error. Then, the syndrome may be represented as follows:

Sᵢ=r(aⁱ)=c(aⁱ)+e(aⁱ)=e(aⁱ) Equation (2)

In equation (2), a is a primitive element.

If it is assumed that the received codeword has m errors locations (i₁, i₂, . . . , iₘ) the syndrome may be represented as follows:

$${S}_{i} = e ( {α}^{i} ) = {\sum }_{l = 1}^{m} {( {a}^{{i}_{l}} )}^{i} , i = 1 , 2 , … 2 t \qquad Equation ( 3 )$$

In equation (3), the value t is the maximum number of errors that can be corrected by a certain BCH code.

In one particular example, the first syndrome checker 212a involves operations at about 800 MHz and a codeword size of 64 user bytes plus 8 parity bytes (i.e., codeword size=72 bytes). In one embodiment, each codeword takes 4 clock cycles to read, and the syndrome check is done at the line rate (e.g., at the end of 4 clock cycles). That is, the line rate is equal to the rate a codeword is read from the memory. Then a received codeword can be delivered to a receive buffer of an interface (e.g., host interface 106), such as a PCIe interface, for the host. In several embodiments, the first syndrome checker 212a is configured to operate at line rate. That is, a codeword may be read from the NVM and provided to the syndrome checker at a preselected rate, and the syndrome checker is configured to perform error checking at the preselected rate. In one embodiment, the first syndrome checker 212a generates a syndrome that is 8 bytes at every 4 clock cycles (e.g., 200 M syndromes per second, or 1 syndrome per clock if the clock of this block operates at 200 MHz instead of 800 MHz). In such case, the first syndrome checker 212a can process 8 bytes per 4 clocks at about 1 percent of the time. The second syndrome checker 212b can be configured in the same way as the first syndrome checker 212a.

The first ping-pong buffer 214a is an optional component and may include multiple buffers. For example, while one or more buffers are written with new data from the syndrome checker, the other buffers may be read such that data may be written and read to/from the ping-pong buffer simultaneously. In one embodiment, the first ping-pong buffer 214a may have a 16×72 register file with 1 read port (e.g., 9 bytes/clock), 1 write port (e.g., 9 bytes/clock), and a width of 9 bytes or 72 bits and a depth of 16 words. The second ping-pong buffer 214b is also an optional component and can be configured in the same way as the ping-pong buffer 214a.

The code word queue 216 stores data (e.g., codewords) to be sent to a host (e.g., host 102) for example via the host interface 106. If a codeword contains error(s), it is held in the queue 216 (i.e., not sent to the host) until the error locations are computed or determined by the ECC circuitry 202, and while or before the data is transmitted, the error bits are flipped or inverted (i.e., corrected) based on the error locations.

The ECC circuitry 202 is located outside of the primary read data path 204 (e.g., data paths 204) and is configured to find or determine the locations of errors in a code word. The first syndrome checker 212a is directly connected to the first ping-pong buffer 214a, which is directly connected to the code word queue 216. In some embodiments, the first syndrome checker 212a is directly connected to the code word queue 216 because the first ping-pong buffer 214a is optional. Similarly, the second syndrome checker 212b is directly connected to the second ping-pong buffer 214b, which is directly connected to the code word queue 216. In some embodiments, the second syndrome checker 212b is directly connected to the code word queue 216 because the second ping-pong buffer 214b is optional. Unlike conventional systems, the ECC circuitry 202 may only operate on read data (e.g., on a codeword read from the NVM 206) if the syndrome checkers (212a, 212b) have determined that an error exists in the codeword. That is, the ECC circuitry 202 may be bypassed or not operated when no error is found in the codeword. In this way, the low latency architecture of FIG. 2 can provide high speed operation that does not involve error checking/location utilizing the ECC circuitry 202 when errors have not been found by the syndrome checkers. For data streams with relatively small amounts of errors, the low latency architecture can provide low latency read access and much improved performance as compared to conventional systems requiring error location determination for each codeword.

In one embodiment, the syndrome failure frequency may be about 1 percent. In such case, the ECC circuitry 202 is configured to process 4 million (M) syndromes per second. In one embodiment, the number of bits used for error locations are 6×9 assuming a maximum number of errors equal to 6. In such case, the error location bandwidth can be 4M×54 bits/second or 27 Mbytes/second. So the ECC circuitry 202 can be configured for providing or determining error locations for each syndrome in an average of 50 clock cycles at 200 MHz. In other embodiments, the ECC circuitry 202 can be configured to operate using other suitable parameters depending on the application and desired operation speed.

In one embodiment, the data path 204 may have a single data path (first data path). For example, the first data path may include a first data block 210a, a first syndrome checker 212a, and a first ping-pong buffer 214a (if used at all since optional). In some embodiments, the data path 204 may have a second data path coupled in parallel to the first data path. For example, the second data path may include a second data block 210b, a second syndrome checker 212b, and a second ping-pong buffer 214b (if used at all since optional). Having multiple parallel data paths (e.g., 2 or more) may reduce the parallelization requirements for each individual path. For instance, a syndrome checker with parallelization of 128 inputs per clock may be used rather than one with parallelization of 256 inputs per clock.

In operation, for example, data (e.g., in the form of a codeword) can be read from the NVM 206 and provided to the first syndrome checker 212a. The syndrome checker 212a can determine whether an error exists in the codeword. If no error exists in the codeword, the syndrome checker 212a can forward the codeword to the code word queue 216 via the ping-pong buffer 214a (optional), and it can then be sent to the host/target (e.g., host 102). This is the fast path 204 to the code word queue 216. If an error exists in the received codeword, the syndrome checker 212a can forward the codeword and/or syndromes to the ECC circuitry 202, which finds the error locations within the codeword, and to the code word queue 216, which fixes the errors based on the error locations from the ECC circuitry 202. For binary data, an error bit may be fixed by flipping or inverting the bit. Then the code word queue 216 sends the fixed data to the host/target. Similar operations may be performed by the second data block 210b, second syndrome checker 212b, and second ping-pong buffer 214b if so configured. Further efficiency can be gained in the ECC circuitry itself as will be discussed in detail below. The first syndrome checker 212a and second syndrome checker 212b may be implemented using any suitable syndrome checkers or methods known in the art.

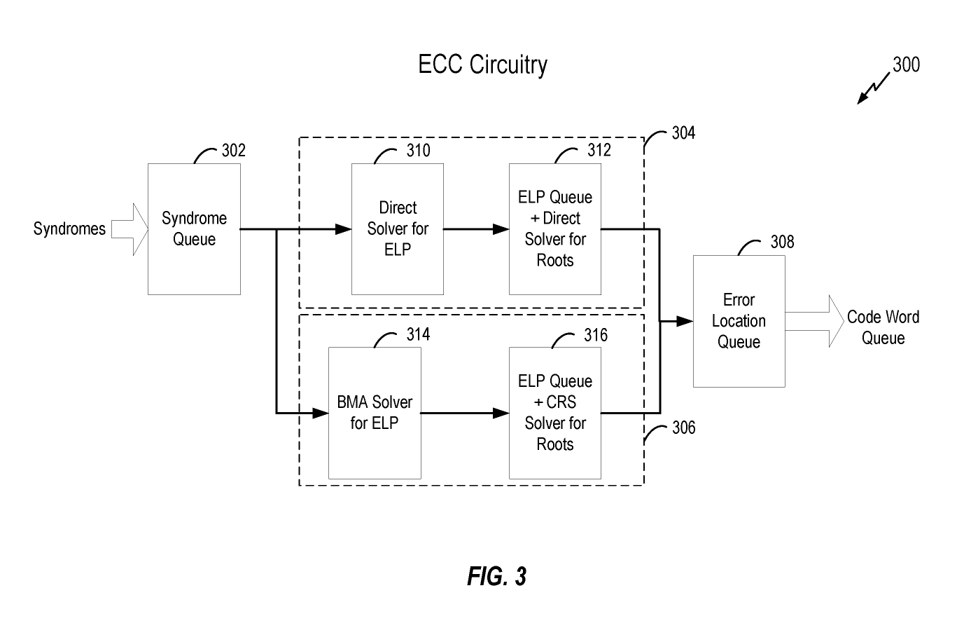

FIG. 3 is a block diagram of an error correction code (ECC) circuitry 300 in accordance with one embodiment of the disclosure. In one embodiment, the ECC circuitry 300 can be used in FIG. 2 for the ECC circuitry 202. The ECC circuitry 300 includes a syndrome queue 302 for storing syndromes, a fast data path 304, a slow data path 306, and an error location queue 308. The fast data path 304 is utilized when the total errors m of the codeword is less than a preselected threshold T (e.g., number of errors less than 4). In some embodiments, the preselected threshold T may have a value of 6 or less. In one particular embodiment, the threshold T may have a value of 4. The slow data path 306 is utilized when the total errors m is equal to, or greater than, the preselected threshold T (e.g., number of errors equal to or greater than 4).

In one embodiment, the fast data path 304 includes a direct solver 310 for error locator polynomials (ELPs) and an ELP queue plus direct solver for ELP roots 312 (direct root solver). The direct solver 310 is configured to determine the coefficients of the ELP corresponding to the syndromes. The direct root solver 312 is configured to determine the roots of the ELP to thereby determine the error locations, which may be stored in the error locator queue 308. The slow path 306 includes a Berlekamp-Massey algorithm (BMA) solver 314 for determining the coefficients of the ELP from the syndromes stored at the syndrome queue 302. The slow path 306 also includes an ELP queue plus Chien Root Search (CRS) solver 316 (CRS root solver) for determining the roots of the ELP to thereby determine the error locations, which may be stored in the error location queue 308.

The syndrome queue 302 may be any suitable type of memory that may be used to store data such as the syndromes determined by the syndrome checkers (212a, 212b) in FIG. 2. For example, the syndrome queue 302 may be a random-access memory (RAM), a dynamic random-access memory (DRAM), a static random-access memory (SRAM), a synchronous dynamic random-access memory (SDRAM), a flash storage, an erasable programmable read-only-memory (EPROM), an electrically erasable programmable read-only-memory (EEPROM), or any suitable data storage device.

In one embodiment, the fast data path 304 may be operated as described below when the total errors m are less than the preselected or predetermined threshold T (e.g., T may be 4 errors). A number of syndromes (Sᵢ) for a received codeword are stored in the syndrome queue 302. Based on these syndromes, the direct solver 310 can determine the coefficients of the corresponding error location polynomial (ELP), which are provided to the direct root solver 312. The direct root solver 312 may have a queue or buffer for receiving the ELP coefficients determined by the direct solver 310, and is configured to determine the roots of the ELP.

The syndromes may be represented in terms of the ELP as follows:

$${S}_{i} = e ( {α}^{i} ) = {\sum }_{l = 1}^{m} {( {a}^{{i}_{l}} )}^{i} = {\sum }_{l = 1}^{m} {Λ}_{l}^{i} , i = 1 , 2 , … 2 t$$

Error location polynomial:

$$Λ ( x ) = {Λ}_{0} + {\sum }_{l = 1}^{m} {Λ}_{l} {x}^{l} , where {Λ}_{0} = 1$$

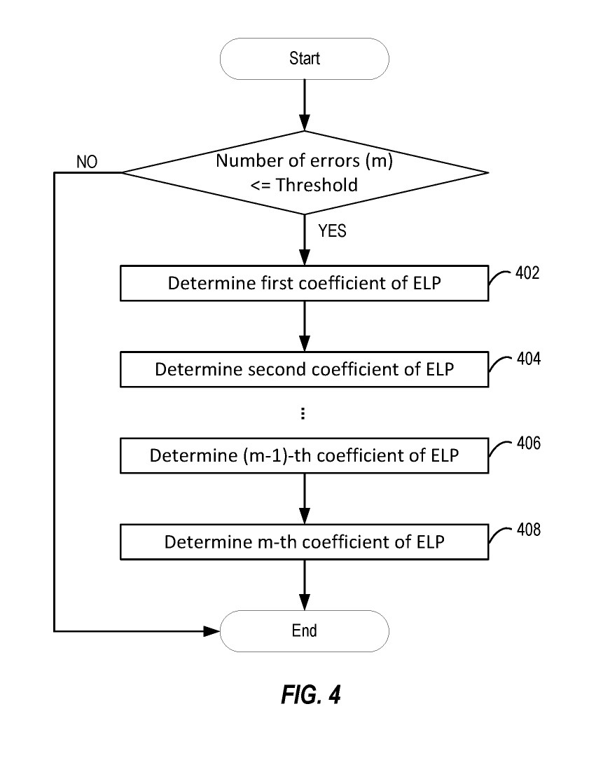

In one embodiment, referring to FIG. 4, if the codeword has a number of bit errors m less than or equal to a certain error threshold T (e.g., T=4 or less), the direct solver 310 is utilized to determine the coefficients (Λ₁, Λ₂, . . . , Λₘ₋₁, and Λₘ) of the ELP at blocks 402 and 404 through blocks 406 and 408. Specific examples are shown below for different number of errors.

If m=1 (first order ELP polynomial), the coefficient of the ELP may be determined as follows:

Λ₁=S₁

If m=2 (second order ELP polynomial), the coefficients of the ELP may be determined as follows:

$${Λ}_{1} = {S}_{1}$$

$${Λ}_{2} = \frac{{S}_{3} + {S}_{1}^{3}}{{S}_{1}}$$

If m=3 (third order ELP polynomial), the coefficients of the ELP may be determined as follows:

$${Λ}_{1} = {S}_{1}$$

$${Λ}_{2} = \frac{{S}_{1}^{2} {S}_{3} + {S}_{5}^{3}}{{S}_{1}^{3} + {S}_{3}}$$

$${Λ}_{3} = ( {S}_{1}^{3} + {S}_{3} ) + {S}_{1} {Λ}_{2}$$

If m=4 (fourth order ELP polynomial), the coefficients of the ELP may be determined as follows:

$${Λ}_{1} = {S}_{1}$$

$${Λ}_{2} = \frac{{S}_{1} ( {S}_{7} + {S}_{1}^{7} ) + {S}_{3} ( {S}_{1}^{5} + {S}_{5} )}{{S}_{3} ( {S}_{1}^{3} + {S}_{3} ) + {S}_{1} ( {S}_{1}^{5} + {S}_{5} )}$$

$${Λ}_{3} = ( {S}_{1}^{3} + {S}_{3} ) + {S}_{1} {Λ}_{2}$$

$${Λ}_{4} = \frac{( {S}_{1}^{2} {S}_{3} + {S}_{5} ) + ( {S}_{1}^{3} + {S}_{3} ) {Λ}_{2}}{{S}_{1}}$$

After the direct solver 310 determines the coefficients of the ELP, they are stored at the direct root solver 312, which may have a queue or any suitable data storage for storing the coefficients. The direct root solver 312 is configured to solve for the roots of the ELP with the determined coefficients. The direct root solver 312 may use any known methods to solve for the roots of the ELP. The root(s) indicate the locations of the error bits in the received codeword. The error locations are stored in the error location queue 308 and may be provided to the code word queue 216 (FIG. 2). Accordingly, the code word queue 216 may correct the error bits in the received codeword based on the error locations. An error bit may be corrected by inverting or flipping the bit. The error location queue 308 may be any suitable type of memory that may be used to store data. For example, the error location queue 308 may be a random-access memory (RAM), a dynamic random-access memory (DRAM), a static random-access memory (SRAM), a synchronous dynamic random-access memory (SDRAM), a flash storage, an erasable programmable read-only-memory (EPROM), an electrically erasable programmable read-only-memory (EEPROM), or the like.

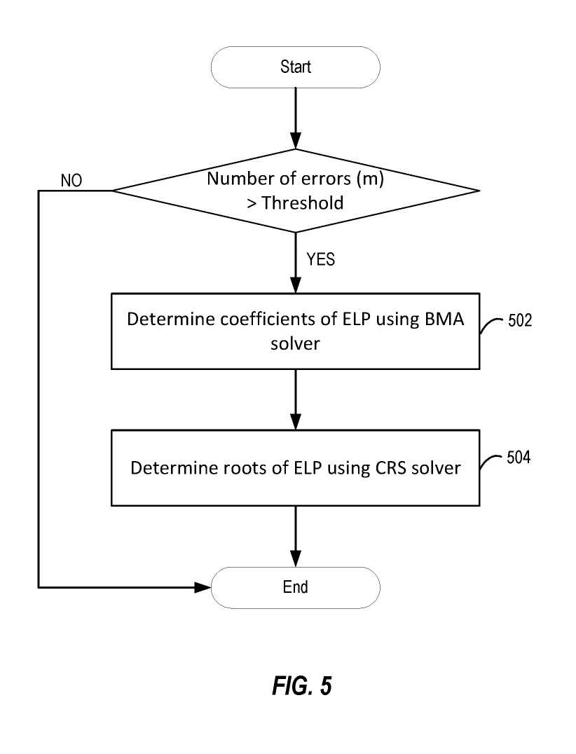

Referring to FIG. 5, if the number of errors of the ELP is greater than the threshold T (e.g., T=6), the coefficients of the ELP may be determined by using the BMA solver 314 at block 502. After the BMA solver 314 determines the coefficients of the ELP, they are stored at the CRS root solver 316, which may have a queue or any suitable data storage for storing the coefficients. Then, the CRS root solver 316 may use a Chien search algorithm to determine the roots of the ELP at block 504. Any known Chien search algorithms or methods may be used. The error locations are stored in the error location queue 308 and may be provided to the code word queue 216 (FIG. 2) for correcting the codeword.

In one embodiment, the direct solver 310 and the BMA solver 314 may be combined into a single solver device. In other embodiments, some or all of the direct solver 310, the direct root solver 312, the BMA solver 314, and the CRS root solver 316 may be included in the same device. In one embodiment, the preselected error threshold (T) may be four rather than six. In other embodiments, the preselected error threshold (T) can have other suitable values. The direct solver 310, the direct root solver 312, the BMA solver 314, and CRS root solver 316 can each be implemented using any corresponding and suitable components as are known in the art.

In effect, the fast path 304 can provide quicker location of the errors in the codeword than the slow path 306. Each of the paths is configured to quickly and efficiently locate the errors based on the expected total number of errors in the syndrome. This two-path approach can provide quicker and more efficient error location than conventional single path approaches.

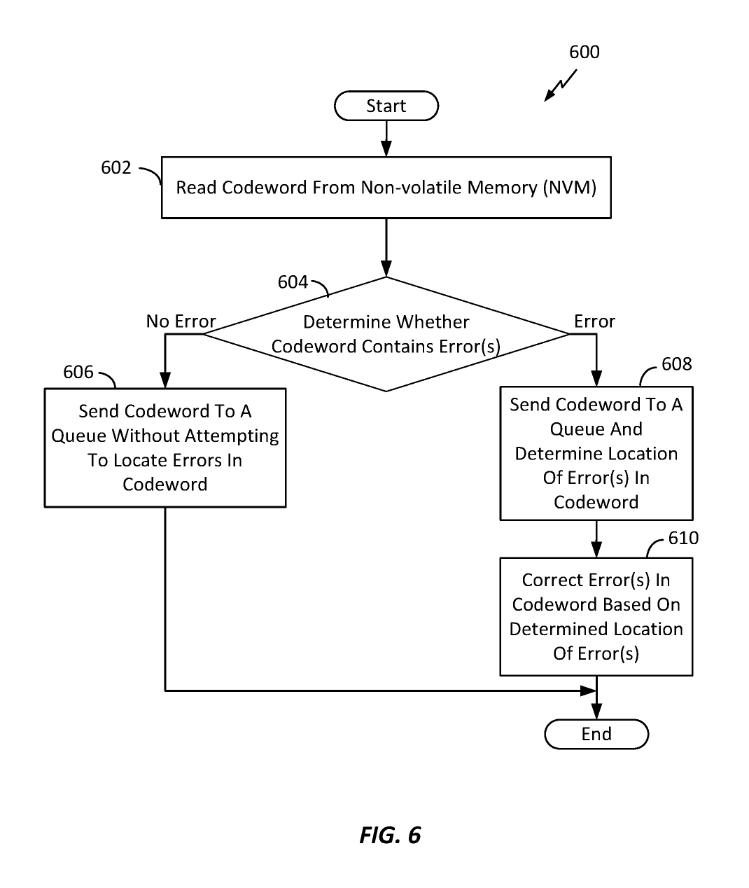

FIG. 6 is a flowchart of a process 600 for providing low latency read access of a non-volatile memory in accordance with one embodiment of the disclosure. In particular embodiments, the process 600 can be executed by the controller 108 and/or NVM 112 of FIG. 1 or another suitable processor. In block 602, the process reads a codeword from a non-volatile memory (NVM). For example, the controller 108 may provide an address and a read signal to the NVM 112. In response, the NVM 112 may output the data (codeword) at the specified address. In block 604, the process 600 determines whether or not the codeword contains error(s). For example, a syndrome checker (e.g., syndrome checkers 212a and 212b of FIG. 2) may be used to determine the syndrome of the codeword. A non-zero syndrome indicates that the codeword has an error.

If the codeword contain no error(s), then the process sends the codeword to the queue without attempting to locate errors in the codeword in block 606. For example, the read path 204 of FIG. 2 may send the codeword to the code word queue 216 or the host 102 without using the ECC circuitry 202 or an equivalent circuitry. If the codeword contains error(s), then the process determines the location(s) of the error(s) in the codeword in block 608. In block 608, even when the codeword has error(s), the codeword may be sent to the queue as in the case of no error. However, the codeword may not be transferred to the host until the error(s) are corrected using the ECC circuitry. For example, the process may determine the error location(s) utilizing the methods illustrated in FIGS. 4 and 5. In block 610, the process corrects the error(s) in the codeword using the determined error location(s). In several embodiments, the corrected data is sent to the host (e.g., host 102 of FIG. 1).

While the above description contains many specific embodiments of the invention, these should not be construed as limitations on the scope of the invention, but rather as examples of specific embodiments thereof. Accordingly, the scope of the invention should be determined not by the embodiments illustrated, but by the appended claims and their equivalents.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed, or multiple may be combined in a single block or state. The example tasks or events may be performed in serial, in parallel, or in some other suitable manner. Tasks or events may be added to or removed from the disclosed example embodiments. The example systems and components described herein may be configured differently than described. For example, elements may be added to, removed from, or rearranged compared to the disclosed example embodiments.

What is claimed is:

1. A storage system for providing low latency read access of a non-volatile memory, the system comprising:
a non-volatile memory (NVM) configured for read access via a primary data path;
a syndrome checker disposed along the primary data path and configured to check a codeword read from the NVM for errors;
an error correction code (ECC) circuitry disposed outside of the primary data path and, if the codeword is determined to contain an error, configured to determine a location of the error in the codeword; and
a queue disposed along the primary data path and configured to:
receive the codeword from the syndrome checker;
if the codeword is determined to contain no error, output the codeword to a host; and
if the codeword is determined to contain the error, correct the error based on the determined location of the error from the ECC circuitry and output the codeword to the host.

2. The storage system of claim 1, wherein the ECC circuitry comprises:
a syndrome queue configured to received one or more syndromes from the syndrome checker;
an error location queue configured to store one or more error locations of the codeword;
a first data path coupled between the syndrome queue and the error location queue; and
a second data path coupled in parallel to the first data path,
wherein components in the first data path and the second data path are configured to determine the one or more error locations of the codeword.

3. The storage system of claim 2, wherein the ECC circuitry is configured to:
if the codeword has a number of errors less than or equal to a threshold, utilize components in the first data path to determine the one or more error locations; and
if the codeword has a number of errors greater than the threshold, utilize components in the second data path to determine the one or more locations.

4. The storage system of claim 2,
wherein the first data path comprises a direct solver and a direct root solver,
wherein the direct solver is configured to determine an error location polynomial (ELP) based on the one or more syndromes, and
wherein the direct root solver is configured to determine one or more roots of the ELP corresponding to the one or more error locations.

5. The storage system of claim 2,
wherein the second data path comprises a Berlekamp-Massey algorithm (BMA) solver and a Chien Root Search (CRS) root solver,
wherein the BMA solver is configured to determine an error location polynomial (ELP) based on the one or more syndromes, and
wherein the CRS root solver is configured to determine one or more roots of the ELP corresponding to the one or more error locations.

6. The storage system of claim 1, further comprising:
a read logic configured to read the codeword from the NVM and to provide the codeword to the syndrome checker at a preselected rate,
wherein the syndrome checker is configured to perform error checking at the preselected rate.

7. The storage system of claim 1, wherein the queue is configured to correct the error of the codeword by inverting a bit at the location determined by the ECC circuitry.

8. The storage system of claim 1, wherein the syndrome checker is directly coupled to the queue via the primary data path.

9. The storage system of claim 1, further comprising:
a buffer,
wherein the syndrome checker is directly coupled to the buffer via the primary data path, and
wherein the buffer is directly coupled to the queue via the primary data path.

10. A method for providing low latency read access of a non-volatile memory, the method comprising:
reading a codeword from a non-volatile memory (NVM);
determining whether the codeword contains an error;
sending, if the codeword contains no error, the codeword to a queue without attempting to locate errors in the codeword;
determining, if the codeword contains the error, a location of the error in the codeword; and
correcting, if the codeword contains the error, the error in the codeword based on the determined location of the error.

11. The method of claim 10, wherein the determining whether the codeword contains the error comprises:
determining a syndrome of the codeword, the syndrome indicative of whether or not the codeword comprises the error.

12. The method of claim 10, wherein the determining the location of the error comprises:
determining one or more syndromes of the codeword;
determining an error location polynomial (ELP) based on the one or more syndromes; and
solving for one or more roots of the ELP utilizing an algorithm based on a number of errors of the codeword, wherein the one or more roots correspond to the location of the errors.

13. The method of claim 10, wherein the determining the location of the error comprises:
determining one or more syndromes of the codeword; and
if the codeword has a number of errors less than or equal to a threshold:
determining, using a direct solver, an error location polynomial (ELP) based on the one or more syndromes; and
determining, using a direct root solver, one or more roots of the ELP, wherein the one or more roots correspond to the location of the error.

14. The method of claim 13, wherein the determining the location of the error further comprises:
if the codeword has a number of errors greater than the threshold:
determining, using a Berlekamp-Massey algorithm (BMA) solver, the ELP based on the one or more syndromes; and
determining, using a Chien Root Search (CRS) solver, one or more roots of the ELP, wherein the one or more roots correspond to the location of the error.

15. The method of claim 10,
wherein the codeword is read from the NVM and provided to a syndrome checker at a preselected rate; and
wherein the determining the error comprises utilizing the syndrome checker to perform error checking at the preselected rate.

16. The method of claim 10, wherein the correcting the error comprises inverting a bit of the codeword at the determined location.

17. The method of claim 10,
wherein the determining the error comprises utilizing a syndrome checker to determine a syndrome of the codeword,
wherein the determining the location of the error comprises utilizing an error correction code (ECC) circuitry to determine the location, and
wherein the syndrome checker is directly coupled to a queue via a primary data path, and the ECC circuitry is disposed outside of the primary data path.

18. The method of claim 10,
wherein the determining the error comprises utilizing a syndrome checker to determine a syndrome of the codeword,
wherein the determining the location of the error comprises utilizing an error correction code (ECC) circuitry to determine the location, and
wherein the syndrome checker is directly coupled to a buffer via a primary data path, the buffer is directly coupled to a queue via the primary data path.

19. An error correction code (ECC) circuitry comprising:
a syndrome queue configured to store one or more syndromes of a codeword;
an error location queue configured to store one or more error locations of the codeword;
a first data path coupled between the syndrome queue and the error location queue; and
a second data path coupled in parallel to the first data path,
wherein if the codeword has a number of errors less than or equal to a threshold, components in the first data path are configured to determine the one or more error locations, and
wherein if the codeword has a number of errors greater than the threshold, components in the second data path are configured to determine the one or more error locations.

20. The ECC circuitry of claim 19, wherein the first data path comprises:
a direct solver configured to determine an error location polynomial (ELP) based on the one or more syndromes; and
a direct root solver configured to determine one or more roots of the ELP, wherein the one or more roots correspond to the one or more error locations.

21. The ECC circuitry of claim 19, wherein the second data path comprises:
a Berlekamp-Massey algorithm (BMA) solver configured to determine an error location polynomial (ELP) based on the one or more syndromes; and
a Chien Root Search (CRS) solver configured to determine one or more roots of the ELP, wherein the one or more roots correspond to the one or more error locations.

22. The ECC circuitry of claim 19, wherein components in the first data path are configured to determine the error locations faster than that of the second data path.
